(19) United States
(12) Patent Application Publication
(10) Pub. No.: US 2009/0231003 A1
(43) Pub. Date: Sep. 17, 2009

(54) VOLTAGE CONTROLLED OSCILLATOR AND PLL AND FILTER USING THE SAME

(75) Inventors: Chien Ming Chen, Hsin-Chu City (TW); Chih-chien Huang, Yunlin Hsien (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/047,405

(22) Filed: Mar. 13, 2008

(51) Int. Cl. H03K 5/00; H03K 3/00; H03L 7/085

(52) U.S. Cl. 327/157; 327/291; 327/553

(57) ABSTRACT

A voltage controlled oscillator (VCO) generating an output voltage. The VCO has a transconductance amplifier, a capacitor, a comparator, and a switch. The transconductance amplifier receives an input voltage and outputs an output current and has a control terminal receiving a control voltage. The capacitor is coupled between the output of the transcondcutance amplifier and a signal ground. The comparator has a first input terminal coupled to the output of the transcondcutance amplifier, a second input terminal receiving a reference voltage, and an output terminal providing the output voltage. The switch is coupled between the output of the transconductance amplifier and the signal ground and controlled by the output voltage. Phase lock loops (PLLs) including the VCO, a filter with Gm/C self-tuning and a method of tuning Gm/C are disclosed as well.

### BACKGROUND OF THE INVENTION

1. Field of the Invention

The invention relates to a voltage controlled oscillator (VCO) and, in particular, to a VCO with a Gm/C integrator and a reset switch.

2. Description of the Related Art

Generally, a filter with group delay equalization is arranged in a data read channel. The filter is used to remove noise from a signal band and increase gain of signals therein. Such a filter with group delay equalization is typically implemented with a Gm/C type filter. As to the Gm/C type filter, the corner frequency Fc is proportional to Gm/C. Gm/C is mainly influenced by process, voltage, and temperature, as known as PVT. As a result, Fc changes with variation in such parameters and error rate of data read is thus influenced. Accordingly, one requirement of the filter with group delay equalization is that remaining its Fc constant while PVT varies. In other words, Gm/C should be not changed by variation in PVT.

In conventional technologies, in addition to the filter with group delay equalization, a self-tuning mechanism is required to keep Gm/C constant even when there is variation in process or temperature. Such self-tuning mechanism is typically implemented with an analog phase lock loop (PLL) having a voltage controlled oscillator (VCO), a phase frequency detector (PFD), a charge pump, and a loop filter, or with a digital PLL having a voltage controlled oscillator (VCO), a frequency detector (FD), and a digital to analog converter (DAC), as shown in FIGS. 1 and 2.

In FIG. 1, the VCO in the analog PLL is a Gm/C type VCO, with the Gm/C thereof proportional to a control voltage. Thus, the output frequency of the Gm/C type VCO is proportional to Gm/C. The analog PLL locks the output frequency (VCO clock) of the Gm/C type VCO at a reference clock frequency (Ref clock). As temperature increases, transconductance Gm drops such that the output frequency of Gm/C type VCO becomes lower than the reference clock frequency. Then, the control voltage is increased accordingly due to negative feedback nature of the analog PLL, so as to pull up the transconductance Gm. As a result, Gm/C is kept at a constant. In addition, the control voltage is also transferred to a Gm/C type filter with group delay equalization such that a corner frequency Fc thereof is controlled. When the temperature decreases, transconductance Gm increases such that the output frequency of Gm/C type VCO exceeds the reference clock frequency. The control voltage is reduced accordingly due to negative feedback nature of the analog PLL, so as to pull down the transconductance Gm. As a result, Gm/C is kept at a constant. In addition, the control voltage is also transferred to a Gm/C type filter with group delay equalization such that a corner frequency Fc thereof is controlled. Similarly, if capacitance C is influenced by PVT, negative feedback nature of the analog PLL can keep Gm/C at a constant as well. Operating principles and functions of the digital PLL are similar to those of the analog PLL.

Self-tuning of Gm/C is accomplished by a Gm/C type VCO. Since a Gm/C type VCO requires several stages of Gm/C circuits, chip area is thus increased, as is cost.

### BRIEF SUMMARY OF THE INVENTION

An embodiment of a voltage controlled oscillator generates an output voltage and comprises a transconductance amplifier, a capacitor, a comparator, and a switch. The transconductance amplifier receives an input voltage and provides an output current and comprises a control terminal receiving a control voltage. The capacitor is coupled between the output of the transconductance amplifier and a signal ground. The comparator has a first input terminal coupled to the output of the transcondcutance amplifier, a second input terminal receiving a reference voltage, and an output terminal providing the output voltage. The switch is coupled between the output of the transconductance amplifier and the signal ground and controlled by the output voltage.

Another embodiment of an analog phase locked loop (PLL) comprises the disclosed voltage controlled oscillator, a phase frequency detector (PFD) receiving an input signal of a reference frequency and the output voltage of the disclosed voltage controlled oscillator, and a charge pump and a loop filter coupled between the PFD and the control terminal of the disclosed voltage controlled oscillator, wherein the control voltage is generated according to the reference frequency and a frequency of the output voltage.

Another embodiment of a digital phase locked loop (PLL) comprises the disclosed voltage controlled oscillator, a digital frequency detector (FD) receiving an input signal of a reference frequency and the output voltage of the disclosed voltage controlled oscillator, and a digital to analog converter (DAC) coupled between the digital FD and the control terminal of the disclosed voltage controlled oscillator, wherein the control voltage is generated according to the reference frequency and a frequency of the output voltage.

Another embodiment of a filter with Gm/C self-tuning is disclosed. The filter comprises a Gm/C type filter and a voltage controlled oscillator (VCO). The Gm/C type filter is controlled by a control voltage and the VCO is coupled to the Gm/C type filter and generates an output voltage. The VCO comprises a transconductance amplifier, a capacitor, a comparator and a switch. The transconductance amplifier receives an input voltage, outputs an output current and comprises a control terminal receiving the control voltage. The capacitor is coupled between the output of the transconductance amplifier and a signal ground. The comparator has a first input terminal coupled to the output of the transcondcutance amplifier, a second input terminal receiving a reference voltage, and an output terminal providing the output voltage. The switch is coupled between the output of the transconductance amplifier and the signal ground and controlled by the output voltage.

Another embodiment of a method of tuning Gm/C according to an embodiment of the invention. The method comprises providing an input signal of a reference frequency; generating a control voltage according to the input signal and a feedback signal, wherein the control voltage is arranged to modify Gm/C of the filter; generating a charging current according to the control voltage and an input voltage; generating the feedback signal by comparing the voltage drop across a capacitor with a reference voltage, and resetting the voltage drop according to the feedback signal.

Another embodiment provides a Gm/C type filter with Gm/C self-tuning. The filter comprises an analog PLL (or a digital PLL) comprising a PFD (or a FD), a charge pump and a loop filter (or a DAC), and a Gm/C type relaxation oscillator. Due to negative feedback nature of the PLL, a transconductrance to capacitance ratio (Gm/C) of the Gm/C type relaxation oscillator is fixed at a constant as is that of the Gm/C type filter. The transcondcutance amplifier and the capacitor can be implemented within a loop of the PLL. Thus, process drift of transcondcutance (Gm) and capacitance (C) are balanced by frequency lock the PLL. In addition, a waste of a large area of a conventional VCO is avoided. Moreover, the circuit can be utilized in an on-line tuning loop, which works in real-time, rather than a off-line calibration.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic diagram of a conventional filter with Gm/C self-tuning;

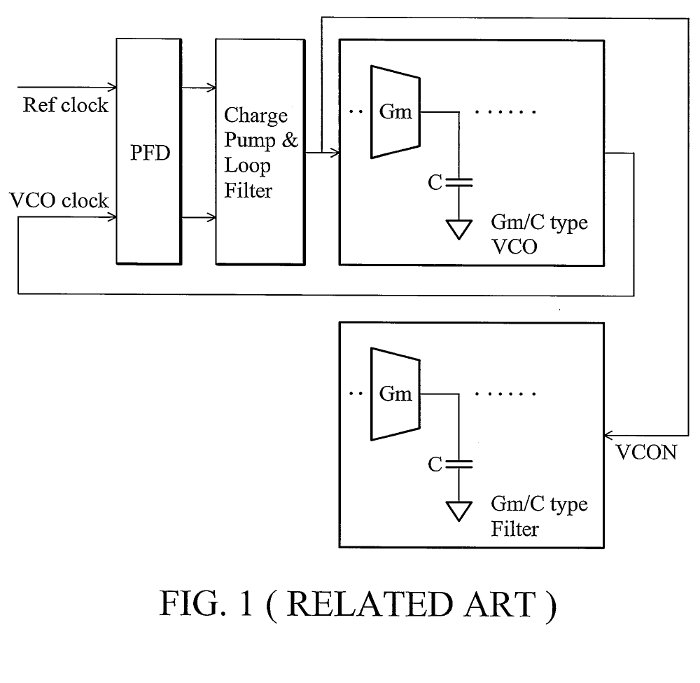

FIG. 2 is a schematic diagram of another conventional filter with Gm/C self-tuning;

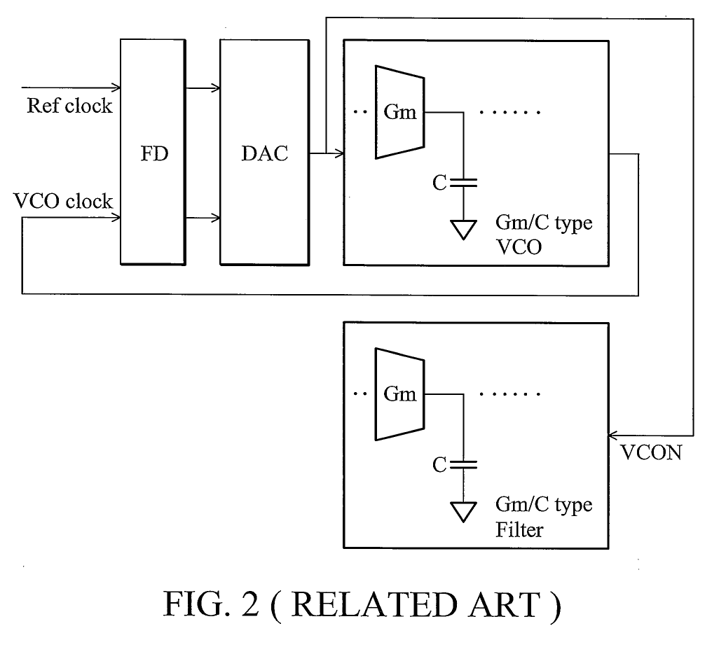

FIG. 3 is a schematic diagram of a filter with a PLL according to an embodiment of the invention;

FIG. 4 is a schematic diagram of a filter with a PLL according to another embodiment of the invention;

FIG. 5 shows a method of tuning Gm/C according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

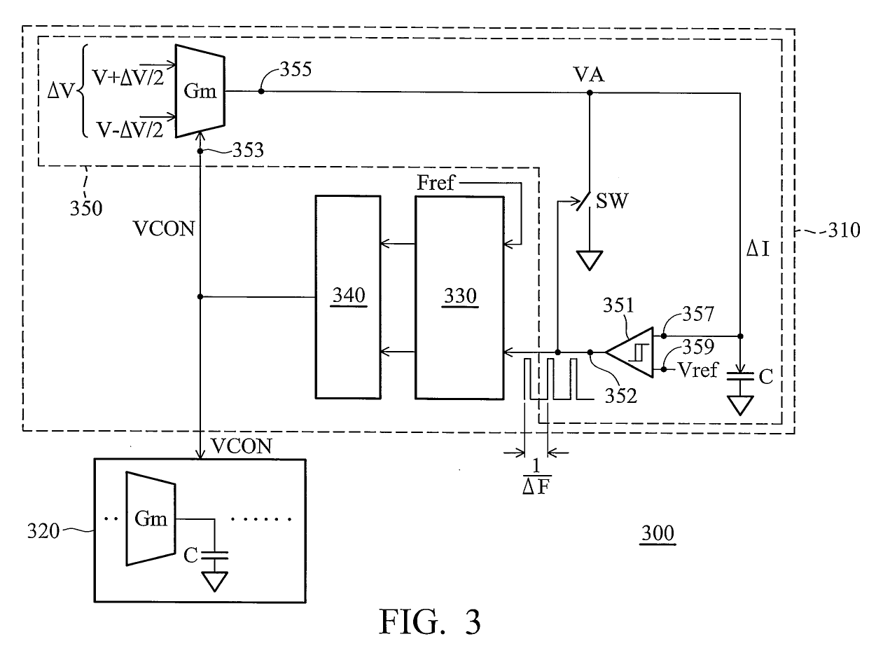

FIG. 3 is a schematic diagram of a filter 300 with a PLL according to an embodiment of the invention. An analog PLL 310 and a Gm/C type filter 320 are coupled thereto. The analog PLL 310 comprises a frequency detector (e.g. a phase frequency detector (PFD) 330), a charge pump and a loop filter 340, and a voltage controlled oscillator (VCO) 350. The PFD 330 receives an input signal of a reference frequency Fref and an output voltage of the VCO 350. The charge pump and the loop filter 340 are coupled between the PFD 330 and the VCO 350. A control terminal 353 of the VCO 350 receives a control voltage VCON generated by the charge pump and the loop filter 340. The control voltage VCON is generated according to the reference frequency Fref and a frequency of the output voltage of the VCO 350.

In FIG. 3, the VCO 350 comprises a transconductance amplifier Gm, a capacitor C, a comparator 351, and a switch SW. The transconductance amplifier Gm receives an input voltage ΔV, and has an output 355 providing an output current ΔI and a control terminal 353 receiving a control voltage VCON. The capacitor C is coupled between the output 355 and a signal ground. The comparator 351 has a first input terminal 357 coupled to the output 355 of the transcondcutance amplifier Gm, a second input terminal 359 receiving a reference voltage Vref, and an output terminal 352 providing the output signal. The switch SW is coupled between the output 355 of the transconductance amplifier Gm and the signal ground and controlled by the output voltage of the VCO 350. The input voltage and the reference voltage may tracks with each other, that is, may be directly or indirectly provided by a same power source. For example, the input voltage ΔV of the transconductance amplifier Gm is generated according to of the reference voltage Vref. In an example, a pair of differential signals with voltages V+ΔV/2 and V−ΔV/2 is provided to the transconductance amplifier Gm such that the input voltage ΔV is received thereby.

The transconductance amplifier Gm receives the input voltage ΔV and transforms it into the output current ΔI. The output current ΔI flows to the capacitor C and the voltage drop across the capacitor C gradually increases. The first input terminal 357 is connected to the output 355 of the transcondcutance amplifier Gm, and thus a voltage VA is applied thereon. Initially, the voltage VA is lower than the reference voltage Vref and the output voltage of the comparator 351 is at a logic state “low”. When the voltage VA exceeds the reference voltage Vref, the output voltage of the comparator 351 switches to a logic state “high”. As a result, the switch SW is turned on thereby and the voltage VA is pulled down to ground. Afterward, the output voltage of the comparator 351 switches accordingly to the logic state “low” again as the voltage VA becomes lower than the reference voltage Vref. Therefore, the output voltage of the comparator 351 periodically switches back and forth between the logic states “low” and “high” and thus acts as a clock signal with a frequency ΔF.

In FIG. 3, the transconductance amplifier Gm generates a current ΔI=ΔV×Gm, where the transconductance Gm is controlled by the control voltage VCON. A time period, during which the voltage drop of the capacitor C is charged to the reference voltage Vref, is 1/ΔF=(C×Vref)/ΔI. Thus, from the two formulae, it is known that ΔF=(Gm/C)×(ΔV/Vref). In the example, due to negative feedback nature of the PLL 310, the frequency ΔF is fixed at the reference frequency Fref. In addition, since the reference voltage Vref is typically generated by, for example, a bandgap reference circuit and the input voltage ΔV may be generated according to the reference voltage Vref, the ratio ΔV/Vref can be fixed at a constant. Consequently, Gm/C is also fixed at a constant. Alternatively, the ratio ΔV/Vref can be adjustable in some embodiments for modulation their relationships.

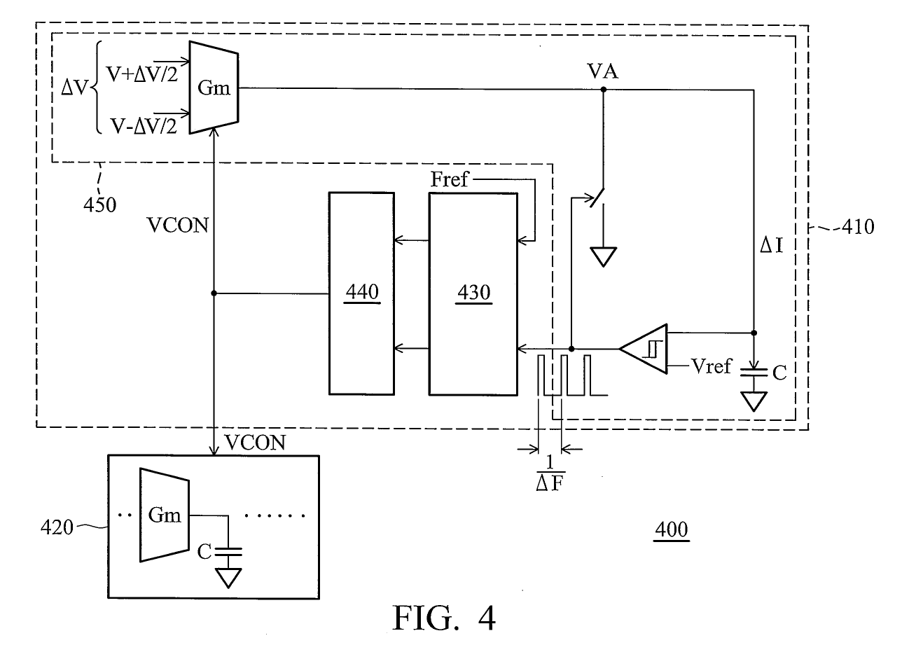

FIG. 4 is a schematic diagram of a filter 400 with a PLL according to another embodiment of the invention. The filter 400 in FIG. 4 is similar to that in FIG. 3 and differs only in that the PLL 410 in FIG. 4 is a digital PLL. The digital PLL 410 comprises a disclosed voltage controlled oscillator (VCO) 450 the same as that in FIG. 3, a digital frequency detector (FD) 430, and a digital to analog converter (DAC) 440. The digital FD 430, e.g. a phase digital detector, receives an input signal of a reference frequency Fref and the output voltage of the VCO 450. The DAC 440 is coupled between the digital FD 430 and the control terminal of the VCO 450. The control terminal of the VCO 450 receives a control voltage VCON generated by the DAC 440. The control voltage VCON is generated according to the reference frequency Fref and a frequency of the output voltage of the VCO 450.

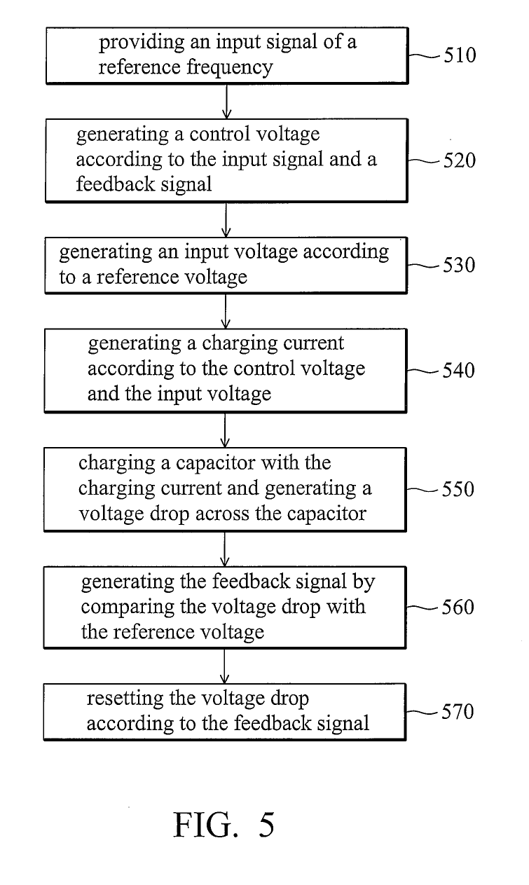

FIG. 5 shows a method of tuning Gm/C according to an embodiment of the invention. The method, which may be utilized in Gm/C filters, VOCs, PLLs or other suitable circuits, comprises providing an input signal of a reference frequency (step 510), generating a control voltage according to the input signal and a feedback signal (step 520), generating an input voltage according to a reference voltage (step 530), generating a charging current according to the control voltage and the input voltage (step 540), charging a capacitor with the charging current and generating a voltage drop across the capacitor (step 550), generating the feedback signal by comparing the voltage drop with the reference voltage (step 560), and resetting the voltage drop according to the feedback signal (step 570).

In another aspect, one embodiment of invention provides a Gm/C type filter with Gm/C self-tuning. The following description is made with reference to FIG. 3. The filter comprises a Gm/C type filter 320 and a voltage controlled oscillator (VCO) 350. The Gm/C type filter 320 is controlled by a control voltage VCON and the VCO 350 is coupled to the Gm/C type filter 320 and generates an output voltage. The VCO 350 comprises a transconductance amplifier Gm, a capacitor C, a comparator 351 and a switch SW. The transconductance amplifier Gm receives an input voltage ΔV, outputs an output current ΔI and comprises a control terminal receiving the control voltage VCON. The capacitor C is coupled between the output of the transconductance amplifier Gm and a signal ground. The comparator 351 has a first input terminal 357 coupled to the output of the transcondcutance amplifier Gm, a second input terminal 359 receiving a reference voltage Vref, and an output terminal 352 providing the output voltage. The switch SW is coupled between the output of the transconductance amplifier Gm and the signal ground and controlled by the output voltage.

That is, the filter comprises an analog PLL (or a digital PLL) comprising a PFD (or a FD), a charge pump and a loop filter (or a DAC), and a Gm/C type relaxation oscillator. Due to negative feedback nature of the PLL, a transconductrance to capacitance ratio (Gm/C) of the Gm/C type relaxation oscillator is fixed at a constant as is that of the Gm/C type filter. The transcondcutance amplifier and the capacitor can be implemented within a loop of the PLL. Thus, process drift of transcondcutance (Gm) and capacitance (C) are balanced by frequency lock the PLL. In addition, a waste of a large area of a conventional VCO is avoided.

While the invention has been described by way of example and in terms of preferred embodiment, it is to be understood that the invention is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A voltage controlled oscillator (VCO) for generating an output voltage, comprising:
a transconductance amplifier receiving an input voltage, outputting an output current and comprising a control terminal receiving a control voltage;
a capacitor coupled between the output of the transconductance amplifier and a signal ground;
a comparator having a first input terminal coupled to the output of the transcondcutance amplifier, a second input terminal receiving a reference voltage, and an output terminal providing the output voltage; and
a switch coupled between the output of the transconductance amplifier and the signal ground and controlled by the output voltage.

2. The VCO as claimed in claim 1, wherein the input voltage of the transconductance amplifier is generated according to the reference voltage.

3. The VCO as claimed in claim 1, wherein the input voltage and the reference voltage are provided by a same power source.

4. The VCO as claimed in claim 1, wherein the control signal is generated according to a reference frequency and a frequency of the output voltage.

5. The VCO as claimed in claim 1, wherein a ratio of the input voltage to the reference voltage is fixed.

6. A phase locked loop (PLL) comprising:
the VCO as claimed in claim 1;
a phase frequency detector (PFD) receiving an input signal of a reference frequency and the output voltage; and
a charge pump and a loop filter coupled between the PFD and the control terminal of the VCO, wherein the control voltage is generated according to the reference frequency and a frequency of the output voltage.

7. The PLL as claimed in claim 6, wherein the input voltage of the transconductance amplifier is generated according to the reference voltage.

8. The PLL as claimed in claim 6, wherein the input voltage and the reference voltage are provided by a same power source.

9. The PLL as claimed in claim 6, wherein a ratio of the input voltage to the reference voltage is fixed.

10. A phase locked loop (PLL) comprising:
the VCO as claimed in claim 1;
a digital frequency detector (FD) receiving an input signal of a reference frequency and the output voltage; and
a digital to analog converter (DAC) coupled between the digital FD and the control terminal of the VCO, wherein the control voltage is generated according to the reference frequency and a frequency of the output voltage.

11. The PLL as claimed in claim 10, wherein the input voltage of the transconductance amplifier is generated according to the reference voltage.

12. The PLL as claimed in claim 10, wherein the input voltage and the reference voltage are provided by a same power source.

13. The PLL as claimed in claim 10, wherein a ratio of the input voltage to the reference voltage is fixed.

14. A filter with Gm/C self-tuning, comprising:
a Gm/C type filter controlled by a control voltage; and
a voltage controlled oscillator (VCO) coupled to the Gm/C type filter and generating an output voltage, comprising:
a transconductance amplifier receiving an input voltage, outputting an output current and comprising a control terminal receiving the control voltage;
a capacitor coupled between the output of the transconductance amplifier and a signal ground;
a comparator having a first input terminal coupled to the output of the transcondcutance amplifier, a second input terminal receiving a reference voltage, and an output terminal providing the output voltage; and
a switch coupled between the output of the transconductance amplifier and the signal ground and controlled by the output voltage.

15. The filter with Gm/C self-tuning as claimed in claim 14, wherein the input voltage of the transconductance amplifier is generated according to the reference voltage.

16. The filter with Gm/C self-tuning as claimed in claim 14, wherein the input voltage and the reference voltage are provided by a same power source.

17. The filter with Gm/C self-tuning as claimed in claim 14, wherein the control signal is generated according to a reference frequency and a frequency of the output voltage.

18. The filter with Gm/C self-tuning as claimed in claim 14, wherein a ratio of the input voltage to the reference voltage is fixed.

19. A method for tuning Gm/C of a filter, comprising:
providing an input signal of a reference frequency;
generating a control voltage according to the input signal and a feedback signal, wherein the control voltage is arranged to modify Gm/C of the filter;
generating a charging current according to the control voltage and an input voltage;
generating the feedback signal by comparing the voltage drop across a capacitor with a reference voltage; and
resetting the voltage drop according to the feedback signal.

20. The method for tuning Gm/C of a filter as claimed in claim 19, wherein the input voltage is generated according to the reference voltage.
